(19) United States
(12) Patent Application Publication
(10) Pub. No.: US 2005/0219815 A1
(43) Pub. Date: Oct. 6, 2005

(54) Heat dissipation module

(75) Inventors: Yi-Sheng Lee, Taoyuan County (TW); Li-Kuang Tan, Taoyuan County (TW)

Correspondence Address: BIRCH STEWART KOLASCH & BIRCH, PO BOX 747, FALLS CHURCH, VA, 22040-0747, US

(73) Assignee: Delta Electronics, Inc.

(21) Appl. No.: 11/090,223

(22) Filed: Mar. 28, 2005

(30) Foreign Application Priority Data
Mar. 31, 2004 (TW) 93108925

(51) Int. Cl. H05K 7/20

(52) U.S. Cl. 361/695

(57) ABSTRACT

A heat dissipation module includes an air conveying device, a first member and a second member. The first member has at least one air inlet, and the second member is formed with a heat transfer enhancing structure on its surface and mounted on a heating element. The second member is coupled to the first member to form a cooling chamber having at least one air vent, and allows the heat transfer enhancing structure to be received therein. The air conveying device draws airflow into and out of the cooling chamber, and the heat transfer enhancing structure defines at least one passage along which the airflow propagates in the cooling chamber.

### RELATED APPLICATIONS

The present application is based on, and claims priority from, Taiwan Application Serial Number 93108925, filed Mar. 31, 2004, the disclosure of which is hereby incorporated by reference herein in its entirety.

### BACKGROUND OF THE INVENTION

(a) Field of the Invention

The present invention relates to a heat dissipation module and, more particularly, to a heat dissipation module having high heat dissipation efficiency.

(b) Description of the Related Art

Nowadays, as the capability of an electronic device is increased, a more capable heat dissipation module that works with the electronic device is needed.

FIG. 1 is a schematic view showing a heat dissipation device 100 installed on a heating element such as a CPU (not shown). The heat dissipation device 100 includes a heat sink 102 and an axial flow fan 104. After the heat sink 102 absorbs the heat generated by the heating element through heat conduction, the airflow induced by the axial flow fan 104 further dissipates the heat absorbed by the heat sink 102.

However, as shown in FIG. 1, according to the conventional way of the conjunction of the fan 104 and the heat sink 102, the airflow induced by the fan 104 and fed into the heat sink 102 may have a high temperature of around 40-45° C. Thus, the temperature difference between the heating element and the airflow is only 25° C. to result in a low heat dissipation efficiency, for a CPU typically has a surface temperature of around 65-70° C.

Further, with the inherent restriction of a common fan motor design, the airflow underneath its stator is very weak; however, the region underneath the stator often neighbors the center portion of the heat sink 102 having highest heat flux. This may result in unevenly heat dissipation.

### BRIEF SUMMARY OF THE INVENTION

Hence, the subject invention is to provide a heat dissipation module having high heat dissipation efficiency and evenly heat dissipation.

According to the invention, a heat dissipation module includes an air conveying device, a first member and a second member. The first member has at least one air inlet, and the second member is formed with a heat transfer enhancing structure on its surface and mounted on a heating element. The second member is coupled to the first member to form a cooling chamber having at least one air vent, and allows the heat transfer enhancing structure to be received in the cooling chamber. The air conveying device draws airflow into and out of the cooling chamber, and the heat transfer enhancing structure defines at least one passage along which the airflow propagates in the cooling chamber. Further, the first member may be a plate-like member, and the second member may be a heat sink.

Through the design of the invention, since the heat transfer enhancing structure received in the cooling chamber defines a continuous air passage inside the cooling chamber, when the air conveying device injects high-pressure air into the cooling chamber, the cooling air sweeps all surfaces of the heat transfer enhancing structure inside the cooling chamber. Hence, the cooling air is in fully contact with all surfaces of the heat sink and its heat transfer enhancing structure to avoid the unevenly heat dissipation. On the other hand, compared to the surface temperature of the heat sink, the continuing refreshed cooling air has a considerable low temperature so that the heat dissipation efficiency is greatly enhanced.

### BRIEF DESCRIPTION OF THE DRAWINGS

FIG. 1 is a schematic diagram of a conventional heat dissipation device.

FIG. 2 shows a schematic diagram illustrating an embodiment according to the invention.

FIG. 3A and FIG. 3B illustrate one design of a plate-like member, where FIG. 3A is a top plan view of the plate-like member and FIG. 3B is a cross section of the plate-like member.

FIG. 3C shows a top plan view of another design of the plate-like member.

FIGS. 4A and 4B illustrate one design of a heat sink according to the invention, where FIG. 4A is a cross section and FIG. 4B is a front view of the heat sink.

FIG. 5 shows a schematic view illustrating a heat sink and an engaging structure complementary to the heat sink and formed on the plate-like member.

FIG. 6 shows a schematic view illustrating a heat sink and another engaging structure complementary to the heat sink and formed on the plate-like member.

FIG. 7 shows a schematic diagram illustrating another embodiment of the invention.

FIG. 8 shows a schematic diagram illustrating another embodiment of the invention.

FIG. 9 shows a schematic diagram illustrating another embodiment of the invention.

FIG. 10 shows a schematic diagram illustrating another embodiment of the invention.

FIG. 11 shows a schematic diagram illustrating another embodiment of the invention.

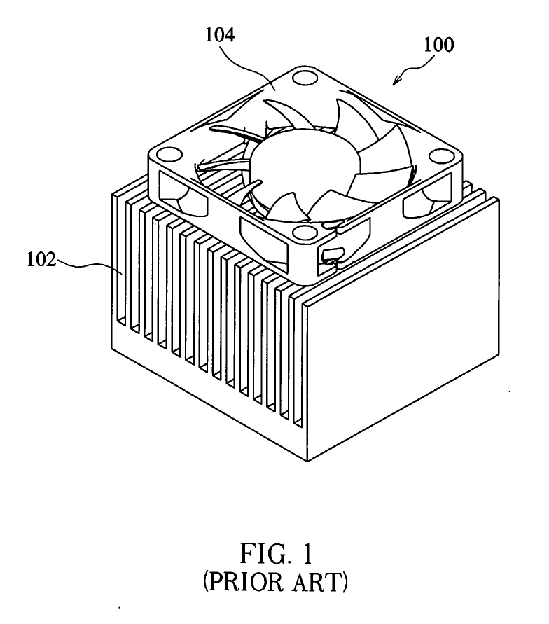

### DETAILED DESCRIPTION OF THE INVENTION

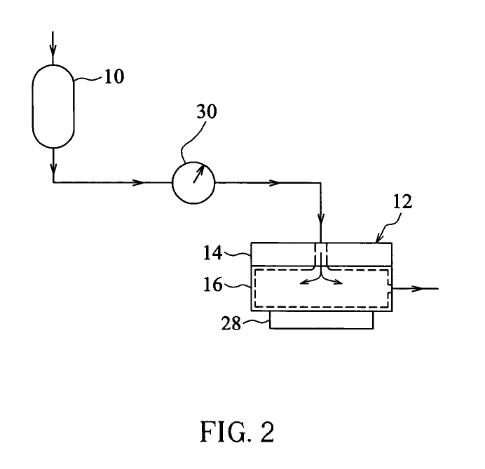

FIG. 2 shows a schematic diagram illustrating an embodiment according to the invention.

Referring to FIG. 2, the heat dissipation module according to this embodiment includes an air compressor 10 and a pre-designed heat dissipation assembly 12. The air compressor 10 is connected to the heat dissipation assembly 12 through an airtight pipe line. After air has been compressed by the compressor 10, it flows at a high speed into the heat dissipation assembly 12 via an air inlet and leaves the heat dissipation assembly 12 via an air vent, along the passage as indicated by the arrows shown in FIG. 2. A pressure controller 30 may be provided in the airtight pipe line between the air compressor 10 and the heat dissipation assembly 12 to adjust air pressure and flow rate.

According to this embodiment shown in FIG. 2, the heat dissipation assembly 12 is constructed by tightly coupling a plate-like member 14 and a heat sink 16 together. The heat sink 16 is made of materials with high thermal conductivity, and its bottom surface is in contact with a heating element 28.

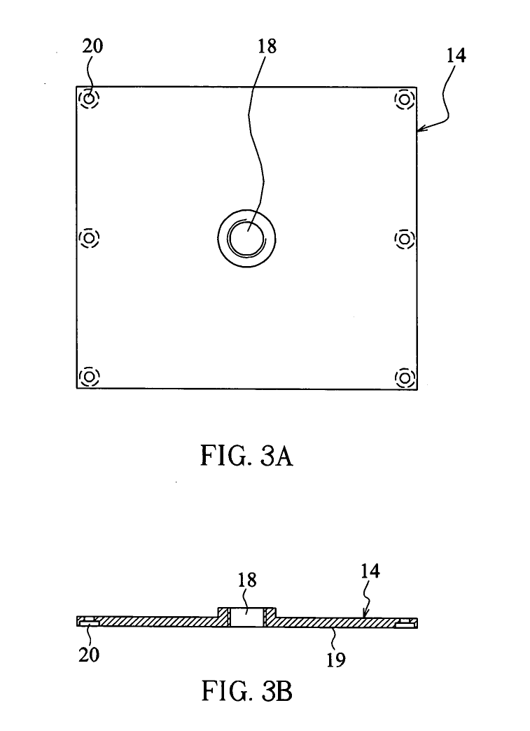

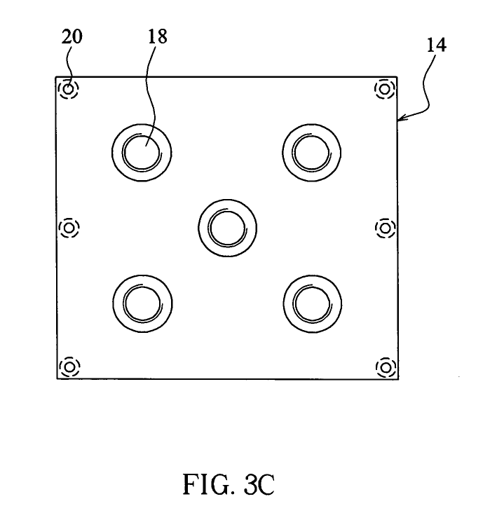

FIGS. 3A and 3B illustrate one design example of the plate-like member 14 according to the invention. The plate-like member 14 is formed with at least one opening 18 at its central location and several mounting holes 20 at its edges.

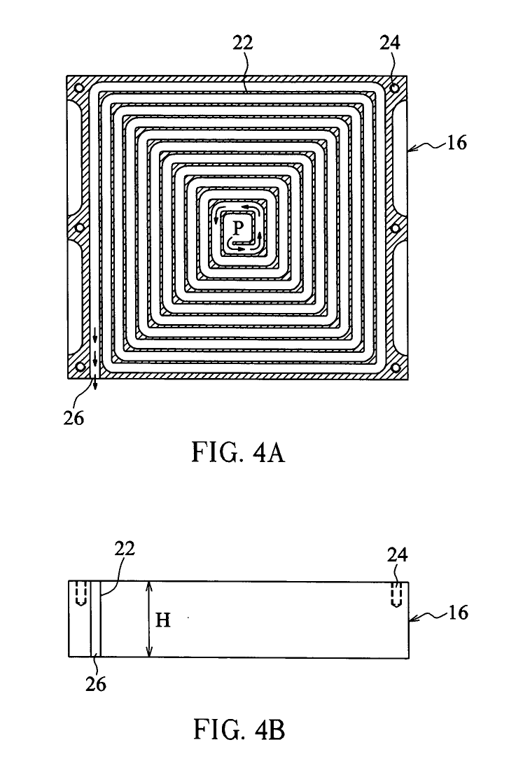

FIGS. 4A and 4B illustrate one design example of the heat sink 16 according to the invention. Referring to FIG. 4A, a spiral fin 22 functioning as a heat transfer enhancing structure is provided on the surface of the heat sink 16, with all parts of the fin 22 having the same height H. The spiral fin 22 may spiral either clockwise or counter-clockwise. The heat sink 16 also has a plurality of mounting holes 24 at its edges. The heat sink 16 is made of a material with a high thermal conductivity.

The plate-like member 14 is tightly fixed on the top of the heat sink 16 to form the heat dissipation assembly 12 through fasteners such as screws or rivets, with the fasteners fitting in the corresponding mounting holes 20 and 24. Thus, the sealed heat dissipation assembly 12 may act as a cooling chamber with an air inlet (the opening 18 of the plate-like member 14) and an air vent (the outlet 26 of the passage defined by the spiral fin 22). Because the spiral fin 22 is provided on the surface of the heat sink 16 with the same height H, when the plate-like member 14 is tightly coupled to the heat sink 16, the top surface of the spiral fin 22 may touch the bottom surface 19 of the plate-like member 14 facing the heat sink 16 to create an air-tight condition. Thus, when the air compressor 10 injects high pressure air into the cooling chamber via the opening 18 of the plate-like member 14, the spiral fin 22 inherently serving as a heat transfer enhancing structure is also used to define the passage along which the airflow propagate in the cooling chamber. Thereby, the air flows along the passage as indicated by the arrows in FIG. 4A, starting at point P and circulating in the passage formed by the spiral fin 22, and exit by the outlet 26 to sweep all surfaces of the spiral fin 22 inside the sealed cooling chamber.

Through the design of the invention, since the shape and position of the spiral fin 22 are designed to cooperative with the opening 18 of the plate-like member 14 to form a continuous air passage inside the cooling chamber, when the air compressor 10 injects high-pressure air into the cooling chamber via the opening 18, the cooling air may sweep all surfaces of the spiral fin 22 inside the cooling chamber. Under the circumstance, the cooling air is in fully contact with all surfaces of the heat sink and its heat transfer enhancing structure. Hence, each part of the inside of the cooling chamber is equally swept by the cooling air to evenly dissipate heat and thus to avoid the unevenly heat dissipation occurring in conventional design. On the other hand, compared to the surface temperature of the heat sink 16, the continuing refreshed cooling-air has a considerable low temperature and thus has an enlarged capability of removing heat to greatly enhance the heat dissipation efficiency.

Further, according to the invention, the number and position of the openings 18 on the plate-like member 14 are not restricted. For example, the plate-like member 14 may be formed with a plurality of openings or air inlets arranged as an array, as in FIG. 3C, or an irregular arrangement.

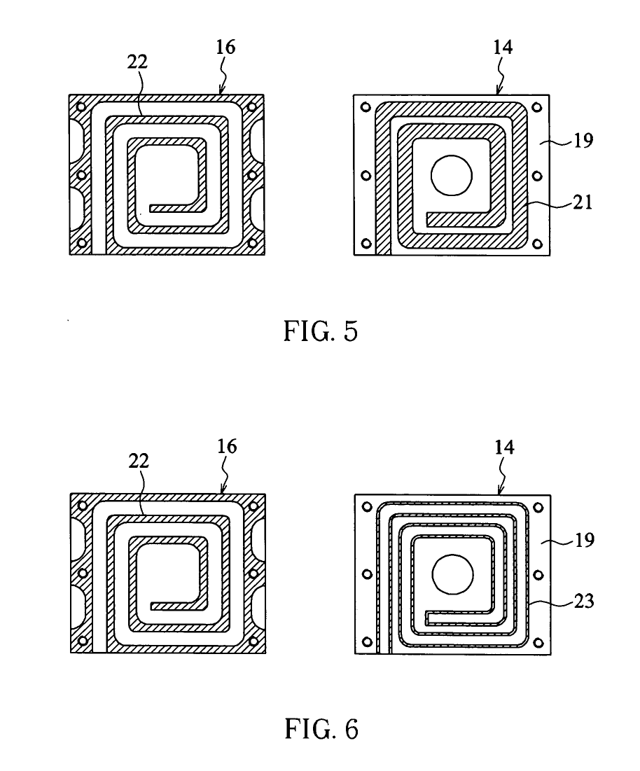

FIG. 5 is a schematic view illustrating the surface of the heat sink 16 on which the spiral fin 22 is provided and the surface 19 of the plate-like member 14 facing the spiral fin 22. As shown in FIG. 5, the surface 19 of the plate-like member 14 facing the heat sink 16 is provided with a spiral bump structure 21 that spreads corresponding to the location of the gap between two adjacent walls of the spiral fin 22. Therefore, when the plate-like member 14 is coupled to the heat sink 16, the bump structure 21 is inserted in the gap and engages with the adjacent walls of the spiral fin 22 to achieve tightly sealing and precisely positioning between them.

In addition, as shown in FIG. 6, the surface 19 of the plate-like member 14 facing the spiral fin 22 is provided with a fin structure 23 having thin walls that are designed to be in fully contact with the sides of the spiral fin 22. Hence, when the plate-like member 14 is mounted on the heat sink 16, the fin structure 23 may engage with the spiral fin 22 to cover the whole air passage. That is, the surface 19 of the plate-like member 14 facing the heat sink 16 may be provided with an engaging structure complementary to the heat transfer enhancing structure to achieve tightly sealing and precisely positioning between the plate-like member 14 and the heat sink 16.

In above-described embodiments, either the bump structure 21 and the spiral fin 22 or the fin structure 23 and the spiral fin 22 can achieve tightly sealing, the height of all parts of the spiral fin 22 and the bump structure 21 can be different.

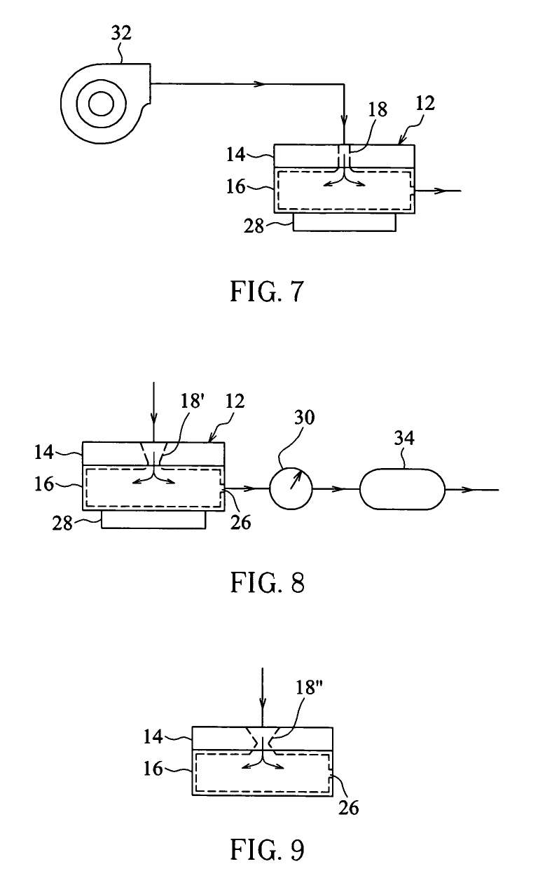

Referring to FIG. 7, a high efficiency blower 32 whose air outlet is connected with the heat dissipation assembly 12 through an airtight pipeline may replace the air compressor. Like the air compressor, the high efficiency blower 32 provides the same function of transmitting cooling air into a cooling chamber and circulating it in defined passages inside the cooling chamber. Further, the shape and area of the opening 18 on the plate-like member 14 is not limited.

FIG. 8 shows a schematic diagram of a heat dissipation module according to another embodiment of the invention. In this embodiment, an air pump 34 connected to the passage outlet 26 of the cooling chamber through an airtight pipeline replaces the air compressor. The air pump 34 may be a vacuum pump. As the air pump 34 pumps out the air from the cooling chamber to create a state of negative pressure, outside air is induced swiftly into the cooling chamber and circulated in defined passages inside the cooling chamber. In this embodiment, the air inlet in the plate-like member 14 is preferably a nozzle opening 18′ with a cross-sectional area converging from outside to the cooling chamber. Thereby, the airflow speed is increased when passing through the converging nozzle opening to cause part internal energy to be transformed into kinetic energy. In that case, the temperature of air passing through the nozzle opening 18′ is lowered and thus the heat dissipation efficiency is further improved.

Naturally, the air inlet on the plate-like member 14 is not restricted to a specific form. For instance, as shown in FIG. 9, it may be shaped as a nozzle opening 18″ with a cross-sectional area converging first and then diverging from outside to the cooling chamber.

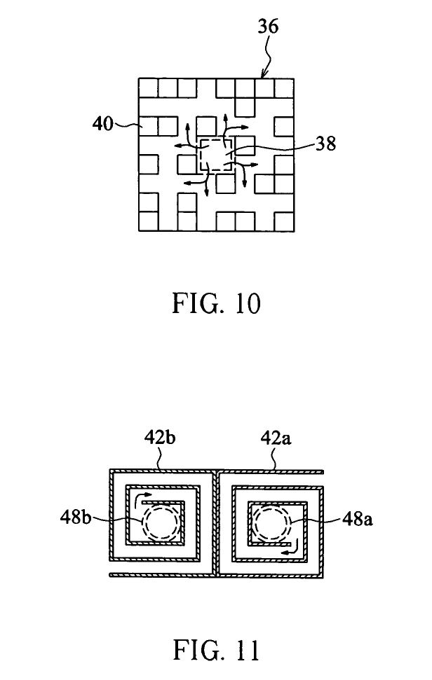

According to the invention, the heat transfer enhancing structure formed on the surface of the heat sink is not restricted to the fin structure. It only needs to form an airflow passage to make the airflow sweep each part of the inside of the cooling chamber after the plate-like member 14 is tightly coupled to the heat sink 16. Referring to FIG. 10, a large number of bumps 40, for instance, may be arranged on the heat sink 36 to create the airflow passage and thus to function as the heat transfer enhancing structure. When air is induced into the cooling chamber via the air inlet 38, it propagates along the passages as indicated by the arrows and exits via a plurality of air vents formed between adjacent bumps 40.

In addition, according to the invention, the number and position of the air inlet is not limited. Referring to FIG. 11, the air inlets 48a and 48b, corresponding to their respective airflow passages formed by fins 42a and 42b, may also be adopted. Accordingly, it can be found that the invention may render the design of a heat dissipation module more flexible, where the number, position, and the corresponding air flow passage of the air inlet are optimized to suit different heat dissipation requirement with respect to different sections of a heating element.

In above-described embodiments, each of the passage couples with one air vent or a plurality of air vents, and couples with one air inlet or a plurality of air inlets.

Also, the plate-like member 14 is used only to provide the air inlet and to cover the heat sink 16 to form a sealed cooling chamber, and its shape is not limited. Further, the plate-like member may be couple to the heat sink 16 by screwing, riveting, engaging or welding.

While the invention has been recited by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

1. A heat dissipation module, comprising:
an air conveying device;
a first member having at least one air inlet; and
a second member formed with a heat transfer enhancing structure on its surface and mounted on a heating element, the second member being coupled to the first member to form a cooling chamber having at least one air vent, and allowing the heat transfer enhancing structure to be received therein;
wherein the air conveying device draws airflow into and out of the cooling chamber, and the heat transfer enhancing structure defines at least one passage along which the airflow propagates in the cooling chamber.

2. The heat dissipation module as recited in claim 1, wherein the first member is a plate-like member, and the second member is a heat sink.

3. The heat dissipation module as recited in claim 1, wherein the first member and the second member are coupled together by screwing, welding, riveting or engaging.

4. The heat dissipation module as recited in claim 1, wherein the second member is made of a material with a high thermal conductivity.

5. The heat dissipation module as recited in claim 1, wherein the heat transfer enhancing structure comprises at least one fin structure or at least one bump structure.

6. The heat dissipation module as recited in claim 5, wherein the fin structure spirals on the surface of the second member.

7. The heat dissipation module as recited in claim 1, further comprising a pressure controller provided between the air conveying device and the cooling chamber.

8. The heat dissipation module as recited in claim 1, wherein the air conveying device is an air compressor, a blower, an air pump or a vacuum pump.

9. The heat dissipation module as recited in claim 1, wherein the air inlet is a nozzle opening with a cross-sectional area converging from outside to the cooling chamber or a nozzle opening with a cross-sectional area converging first and then diverging from outside to the cooling chamber.

10. The heat dissipation module as recited in claim 1, wherein each of the passage couples with one air vent or a plurality of air vents.

11. The heat dissipation module as recited in claim 10, wherein each of the passage couples with one air inlet or a plurality of air inlets.

12. A heat dissipation module, comprising:
an air conveying device; and
a cooling chamber having at least one air inlet and at least one air vent, contacted with a heating element, and provided with a heat transfer enhancing structure;
wherein the air conveying device draws airflow into and out of the cooling chamber, and the heat transfer enhancing structure defines at least one passage along which the airflow propagate in the cooling chamber.

13. The heat dissipation module as recited in claim 12, wherein the cooling chamber is formed by coupling a first member and a second member together, wherein the first member is formed with the air inlet, and the second member is provided with the heat transfer enhancing structure.

14. The heat dissipation module as recited in claim 13, wherein the first member and the second member are coupled by screwing, welding, riveting or engaging.

15. The heat dissipation module as recited in claim 12, wherein the heat transfer enhancing structure comprises at least one fin structure or at least one bump structure.

16. The heat dissipation module as recited in claim 15, wherein the fin structure spirals in the cooling chamber.

17. The heat dissipation module as recited in claim 12, wherein each of the passage couples with one air vent or a plurality of air vents.

18. The heat dissipation module as recited in claim 17, wherein each of the passage couples with one air inlet or a plurality of air inlets.

19. The heat dissipation module as recited in claim 12, wherein the air conveying device is an air compressor, a blower, an air pump or a vacuum pump.

20. The heat dissipation module as recited in claim 12, wherein the air inlet is a nozzle opening with a cross-sectional area converging from outside to the cooling chamber or a nozzle opening with a cross-sectional area converging first and then diverging from outside to the cooling chamber.
